(19) United States
(12) Patent Application Publication
(10) Pub. No.: US 2025/0212667 A1
(43) Pub. Date: Jun. 26, 2025

(54) TRANSPARENT DISPLAY DEVICE

(71) Applicant: LG Display Co., Ltd., Seoul (KR)

(72) Inventors: Intae Ko, Paju-si (KR); Hyunjik Bae, Paju-si (KR); Jin-Uk Lee, Paju-si (KR)

(73) Assignee: LG Display Co., Ltd., Seoul (KR)

(21) Appl. No.: 18/953,832

(22) Filed: Nov. 20, 2024

(30) Foreign Application Priority Data
Dec. 26, 2023 (KR) 10-2023-0191611

(51) Int. Cl. H10K 59/80

(52) U.S. Cl. CPC H10K 59/8792

(57) ABSTRACT

A transparent display device in one example includes a first substrate having a transmissive area that transmit an external light and a non-transmissive area that does not transmit the external light, a light emitting device disposed in the non-transmissive area on the first substrate to emit light thereon, and an organic pattern layer disposed in the transmissive area on the first substrate. The light emitting device includes a first electrode disposed in an emission area, a light emitting layer disposed on the first electrode, and a second electrode disposed on the light emitting layer. The second electrode is disposed in an area in which the organic pattern layer is not disposed and is in contact with an edge of the organic pattern layer.

### CROSS-REFERENCE TO RELATED APPLICATIONS

This application claims priority to Korean Patent Application No. 10-2023-0191611 filed in the Republic of Korea on Dec. 26, 2023, the entire contents of which are hereby expressly incorporated by reference into the present application.

### BACKGROUND

### Technical Field

The present disclosure relates to a transparent display device.

### Discussion of the Related Art

With advancement in information-oriented societies, demands for display devices that display an image have increased in various forms. Various types of display devices such as a liquid crystal display (LCD) device, a plasma display panel (PDP) device, a Quantum dot Light Emitting Display (QLED), and an organic light emitting display (OLED) device have been widely utilized.

In recent years, there has been active research on the display devices that allow users to view objects or images located on the rear surface of the display device. The transparent display device can include a transmissive area to allow external light to pass through and can have a high light transmittance in the display area through the transmissive area.

### SUMMARY OF THE DISCLOSURE

The present disclosure is directed to providing a transparent display device, which substantially obviate one or more problems due to limitations and disadvantages of the related art.

An aspect of the present disclosure is directed to providing a transparent display device, which is capable of improving light transmittance.

Another aspect of the present disclosure is directed to providing a transparent display device, which is capable of preventing an occurrence of the Mura phenomenon and the light leakage phenomenon.

Another aspect of the present disclosure is directed to providing a transparent display device, which is capable of realizing ESG (Environment/Social/Governance) by reducing the generation of greenhouse gases due to the manufacturing process for producing the display device.

Additional advantages and features of the disclosure will be set forth in part in the description which follows and in part will become apparent to those having ordinary skill in the art upon examination of the following or can be learned from practice of the disclosure. Other benefits of the disclosure can be realized and attained by the structure particularly pointed out in the written description and claims hereof as well as the appended drawings.

To achieve these and other advantages and in accordance with the purpose of the disclosure, as embodied and broadly described herein, there is provided a transparent display device including a first substrate including a transmissive area that transmit an external light and a non-transmissive area that does not transmit the external light thereon; a light emitting device disposed in the non-transmissive area on the first substrate to emit light; and an organic pattern layer disposed in the transmissive area on the first substrate, wherein the light emitting device includes: a first electrode disposed in an emission area; a light emitting layer disposed on the first electrode; and a second electrode disposed on the light emitting layer, wherein the second electrode is disposed in an area in which the organic pattern layer is not disposed and is in contact with an edge of the organic pattern layer.

In another aspect of the present disclosure, there is provided a transparent display device including a transmissive area transmitting an external light; an emission area emitting light; a light emitting device disposed in the emission area and including a first electrode, a light emitting layer, and a second electrode; an organic pattern layer, at least a portion of the organic pattern layer being disposed on the same layer as the second electrode of the light emitting device; and a black matric disposed to correspond the light emitting device in the emission area, wherein the second electrode comprises an opening area overlapping at least a portion of the transmissive area and at least a portion of an area in which the black matrix is disposed, and wherein the organic pattern layer is disposed in the opening area of the second electrode

It is to be understood that both the foregoing general description and the following detailed description of the present disclosure are exemplary and explanatory and are intended to provide further explanation of the disclosure as claimed.

### BRIEF DESCRIPTION OF THE DRAWINGS

The accompanying drawings, which are included to provide a further understanding of the disclosure and are incorporated in and constitute a part of this application, illustrate embodiments of the disclosure and together with the description serve to explain the principle of the disclosure. In the drawings:

FIG. 1 is plan view schematically illustrating a transparent display device according to one or more embodiments of the present disclosure;

FIG. 2 is an example of a region A illustrated in FIG. 1;

FIG. 3 is an example of a circuit diagram of a subpixel illustrated in FIG. 2;

FIG. 4 is a cross-sectional view illustrating an example taken along line I-I′ illustrated in FIG. 2;

FIG. 5 is a plan view illustrating an example of a second electrode of a light emitting device and an organic pattern layer according to aspects of the present disclosure;

FIG. 6 is a cross-sectional view illustrating an example of a method for forming the organic pattern layer according to aspects of the present disclosure;

FIG. 7 is a cross-sectional view illustrating an example of a method for forming the second electrode of the light emitting device according to aspects of the present disclosure;

FIG. 8 is a graph for illustrating an example of the light transmittance of the organic pattern layer according to aspects of the present disclosure;

FIG. 9 illustrates a stacked structure according to one example of a region B of FIG. 4;

FIG. 10 illustrates a stacked structure according to one example of a region C of FIG. 4;

FIG. 11 is a cross-sectional illustrating another example taken along line I-I′ illustrated in FIG. 2; and

FIG. 12 is a plan view illustrating another example of the second electrode of the light emitting device and an organic pattern layer according to aspects of the present disclosure.

### DETAILED DESCRIPTION OF THE EMBODIMENTS

Advantages and features of the present disclosure, and implementation methods thereof will be clarified through following embodiments described with reference to the accompanying drawings. The present disclosure can, however, be embodied in different forms and should not be construed as limited to the embodiments set forth herein. Rather, these embodiments are provided so that this disclosure will be thorough and complete, and will fully convey the scope of the present disclosure to those skilled in the art. Furthermore, the present disclosure is only defined by scopes of claims.

A shape, a size, a ratio, an angle, and a number disclosed in the drawings for describing embodiments of the present disclosure are merely an example, and thus the present disclosure is not limited to the illustrated details. Like reference numerals refer to like elements throughout. In the following description, when the detailed description of the relevant known technology is determined to unnecessarily obscure the important point of the present disclosure, the detailed description will be omitted. In a case where “comprise,” “have,” and “include” described in the present disclosure are used, another part can be added unless “only” is used. The terms of a singular form can include plural forms unless referred to the contrary.

In construing an element, the element is construed as including an error range although there is no explicit description.

In describing a positional relationship, for example, when a position relation between two parts is described as “on”, “over”, “under”, and “next”, one or more other parts can be disposed between the two parts unless “just” or “direct” is used.

In describing a temporal relationship, for example, when a temporal precedence relationship is described such as “after”, “following”, “next”, “before”, etc., it can include cases that are not consecutive unless “immediately” or “directly” are used.

It will be understood that, although the terms “first,” “second,” etc. can be used herein to describe various elements, these elements should not be limited by these terms. These terms are only used to distinguish one element from another. For example, a first element could be termed a second element, and, similarly, a second element could be termed a first element, without departing from the scope of the present disclosure.

The term “at least one” should be understood as including any and all combinations of one or more of the associated listed items. For example, the meaning of “at least one of a first item, a second item, and a third item” denotes the combination of all items proposed from two or more of the first item, the second item, and the third item as well as the first item, the second item, or the third item. Further, the term “can” fully encompasses all the meanings and coverages of the term “may.”

Features of various embodiments of the present disclosure can be partially or totally coupled to or combined with each other, and can be variously inter-operated and driven technically. The embodiments of the present disclosure can be carried out independently from each other or can be carried out together with a co-dependent relationship.

Hereinafter, with reference to the accompanying drawings, one example of a display device according to the present disclosure is described. In assigning reference numerals to the components in each drawing, the same component can have the same numeral as far as possible, even if it is shown in different drawings. In addition, when the detailed description of the relevant known technology is determined to unnecessarily obscure the important point of the present disclosure, the detailed description will be omitted.

Hereinafter, with reference to the accompanying drawings, one or more embodiments of the present disclosure will be described. All the components of each display device according to all embodiments of the present disclosure are operatively coupled and configured.

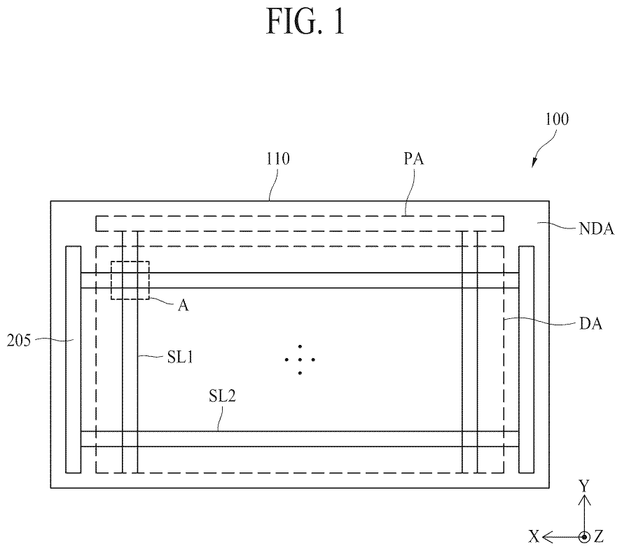

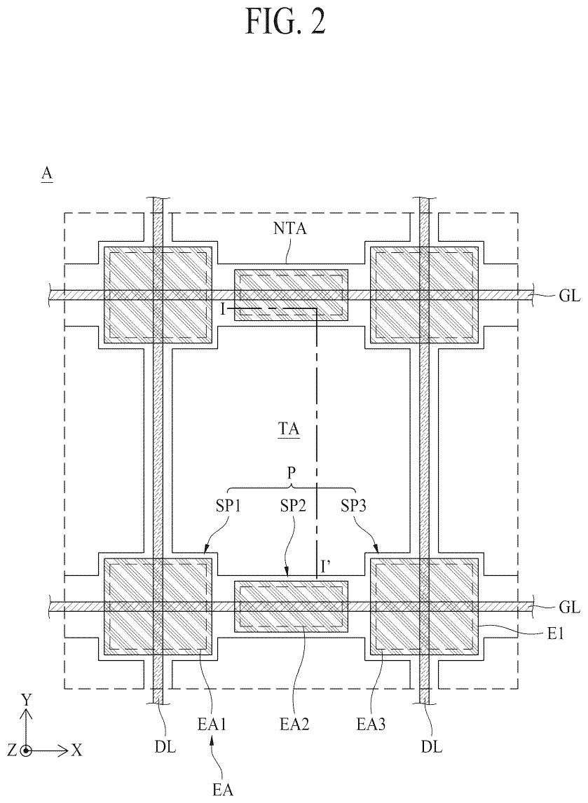

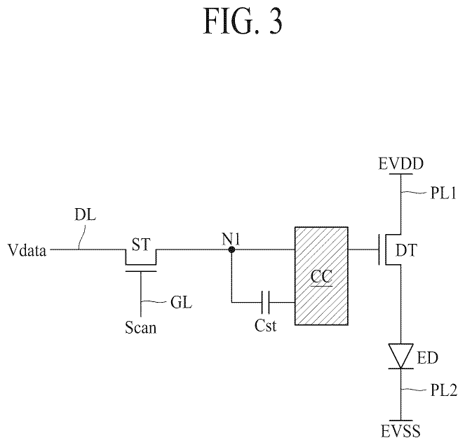

FIG. 1 is plan view schematically illustrating a transparent display device according to one or more embodiments of the present disclosure. FIG. 2 is an example of a region A illustrated in FIG. 1. FIG. 3 is an example of a circuit diagram of a subpixel illustrated in FIG. 2.

Hereinafter, an X axis represents a direction parallel to a gate line, a Y axis represents a direction parallel to a data line, and a Z axis represents a height direction of a transparent display device 100. However, other variations are possible.

An example where a transparent display device 100 according to one or more embodiments of the present disclosure is implemented as an organic light emitting display apparatus will be mainly described, but the transparent display device 100 can be implemented as a liquid crystal display (LCD) apparatus, a plasma display panel (PDP), a quantum dot light emitting display (QLED) apparatus, or an electrophoresis display apparatus.

Referring to FIGS. 1 to 2, the transparent display device 100 according to one or more embodiments of the present disclosure can include a transparent display panel 110. The transparent display panel 110 can be divided into a display area DA (or active area) and a non-display area NDA (or non-active area). The display area DA includes a plurality of pixels P and displays images. The non-display area NDA does not display the images. The non-display area NDA can surround the display area DA entirely or only in part.

The non-display area NDA can include a pad area PA with pads disposed thereon and at least one scan driver 205. The scan driver 205 can be formed in a gate driver in panel GIP type in the non-display area NDA outside of one side or both sides of the display area DA. Alternatively, the scan driver 205 can be fabricated as a driver chip, mounted on a flexible film, and attached to the non-display area NDA outside of one side or both sides of the display area DA in tape automated bonding TAB type.

The display area DA can include first signal lines SL1, second signal lines SL2, and pixels P. The first signal lines SL1 can extend in the display area DA in a first direction (e.g., in the Y axis direction). In one example, the first signal lines SL1 can be data lines, but they are not necessarily limited to. The first signal lines SL1 can include at least one of a first power line, a second power line, and a reference line.

The second signal lines SL2 can extend from the display area DA in a second direction (e.g., in the X axis direction) and can intersect the first signal lines SL1 in the display area DA. In one example, the second signal lines SL2 can be gate lines, but they are not necessarily limited thereto.

As shown in FIG. 2, the display area DA includes a transmissive area TA and a non-transmissive area NTA. The transmissive area TA is an area that transmits most of the light incident from the outside. The non-transmissive area NTA is an area that does not transmit most of the light incident from the outside. For example, the transmissive area TA can have a light transmittance greater than α%, and the non-transmissive area NTA can have a light transmittance less than β%. In this example, α is greater than β, and each of α and β can be a positive number. The transparent display device 100 can allow viewing of an object or background scenes that are located at a rear surface of the transparent display device 100 due to the transmissive area TA of the transparent display panel 110.

The non-transmissive area NTA includes an emission area EA in which a plurality of pixels P are provided to emit light. The non-transmissive area NTA further includes non-emission area disposed between the emission areas EA. Each of the plurality of pixels P can include at least two subpixels SP. For example, each of the plurality of pixels P can include a first subpixel SP1, a second subpixel SP2, and a third subpixel SP3. The first subpixel SP1 can include a first emission area EA1 that emits light of a first color. The second subpixel SP2 can include a second emission area EA2 that emits light of a second color. The third subpixel SP3 can include a third emission area EA3 that emits a third color light. But they are not necessarily limited thereto. Each of the plurality of pixels P can further include a fourth subpixel SP4 that emits white light.

For example, the first to third emission areas EA1, EA2, and EA3 can emit light of different colors. For example, the first emission area EA1 can emit green light, and the second emission area EA2 can emit red light. The third emission area EA3 can emit blue light. However, they are not necessarily limited thereto. Additionally, the arrangement order of each subpixels SP1, SP2, and SP3 can be changed in various ways.

The non-transmissive area NTA can include the data lines DL and the gate lines GL connecting to the subpixels SP1, SP2, and SP3. The data lines DL can be extended from the non-transmissive area NTA in the first direction (e.g., in the Y axis direction), and can supply a data voltage to each of the subpixels SP1, SP2, and SP3. The gate lines GL can be extended from the non-transmissive area NTA in the second direction (e.g., in the X axis direction) and can supply a scan signal to each of the subpixels SP1, SP2, and SP3. The data lines DL and the gate lines GL can be arranged to overlap with the subpixels SP1, SP2, and SP3.

Each of the subpixels SP1, SP2, and SP3 is turned on by the scan signal, and when the data voltage of the data line DL is supplied to a gate electrode of a driving transistor, a light emitting device can emit according to a drain-to-source current of the driving transistor.

Referring to FIG. 3, each of the subpixels SP1, SP2, and SP3 can have 2T1C structure including two transistors DT and ST and one capacitor Cst, but it is not necessarily limited thereto. Each of the subpixels SP1, SP2, and SP3 can further include a compensation circuit CC. In this example, each of the subpixels SP1, SP2, and SP3 can have various structures, such as 3T1C, 4T2C, 5T2C, 6T1C, 6T2C, 7T1C, 7T2C, etc.

Each of the transistors DT and ST of each of the subpixels SP1, SP2, and SP3 can include a gate electrode, a source electrode, and a drain electrode. Since the source electrode and the drain electrode are not fixed and can be changed according to the direction of the voltage and current applied to the gate electrode, one of the source electrode and the drain electrode can be represented as a first electrode and the other can be represented as a second electrode. The transistors DT and ST of each subpixel SP1, SP2, and SP3 can use at least one of a polysilicon semiconductor, an amorphous silicon semiconductor, and an oxide semiconductor. The transistors DT and ST can be P-type or N-type, or a mixture of P-type and N-type.

The light emitting device ED can include an anode electrode connected to the driving transistor DT, a cathode electrode supplied with a second supply voltage EVSS from a second power line PL2, and a light emitting layer between the anode electrode and the cathode electrode. The anode electrode can be an independent electrode for each light emitting device ED, while the cathode electrode can be a common electrode shared by all light emitting devices ED. When a driving current is supplied from the driving transistor DT to the light emitting device ED, electrons are injected from the cathode electrode into the light emitting layer, holes are injected from the anode electrode into the light emitting layer to emit fluorescent material or phosphorescent material by recombination of the electrons and the holes in the light emitting layer, thereby generating light with a brightness proportional to a value of the driving current.

In each of the subpixels SP1, SP2, and SP3, the driving transistor DT is connected between the anode electrode of the light emitting device ED and a first power line PL1 supplying the driving voltage EVDD. Here, the driving voltage EVDD is applied to the first electrode of the driving transistor DT.

The driving transistor DT is a transistor that drives the light emitting device ED and controlled by the voltage applied to the gate electrode to supply current to the light emitting device ED. Accordingly, the light emitting device ED can be driven.

In each of subpixels SP1, SP2, and SP3, a switching transistor ST is connected between a first node N1 of the driving transistor DT and the data line DL. The switching transistor ST is controlled by a scan signal Scan supplied from the gate line GL to apply the data voltage Vdata supplied from the data line DL to the first node N1.

In each of the subpixels SP1, SP2, and SP3, a capacitor Cst is connected to the first node N1 and the voltage applied to the first node N1 is charged in the capacitor Cst. The capacitor Cst can supply the charged data driving voltage to the driving transistor DT. The capacitor Cst can be a storage capacitor.

The compensation circuit CC can be disposed to compensate for a threshold voltage, etc., of the driving transistor DT. The compensation circuit CC can include one or more transistors. The compensation circuit CC can include one or more transistors and capacitors, and can be configured in various ways depending on the compensation method. Each of the subpixels comprising the compensation circuit CC can have various structures, such as 3T1C, 4T2C, 5T2C, 6T1C, 6T2C, 7T1C, 7T2C, etc.

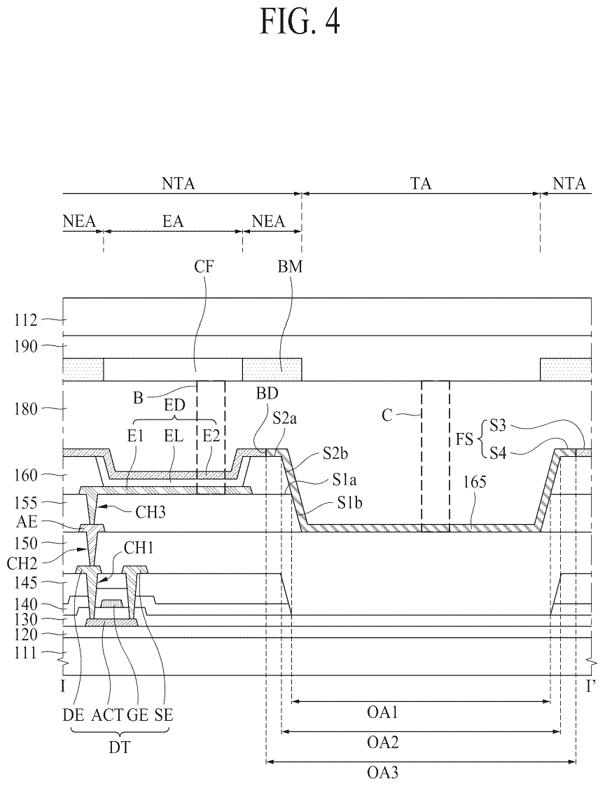

Hereinafter, each components of the transparent display panel 110 according to one or more embodiments of the present disclosure will be described in more detail with reference to FIGS. 4 to 10.

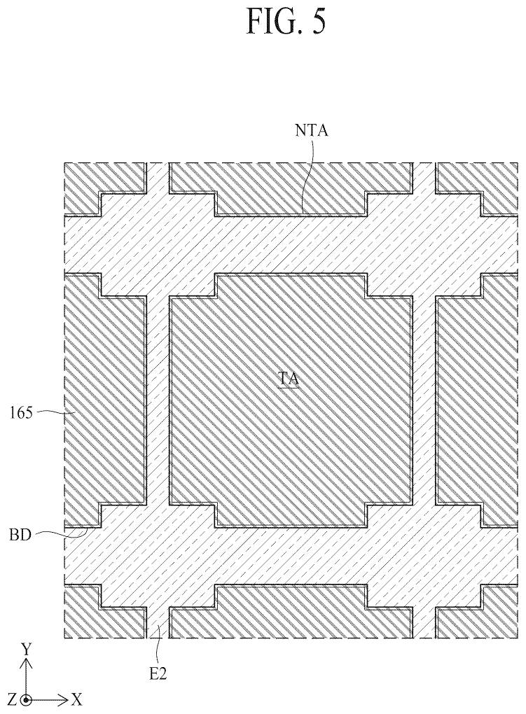

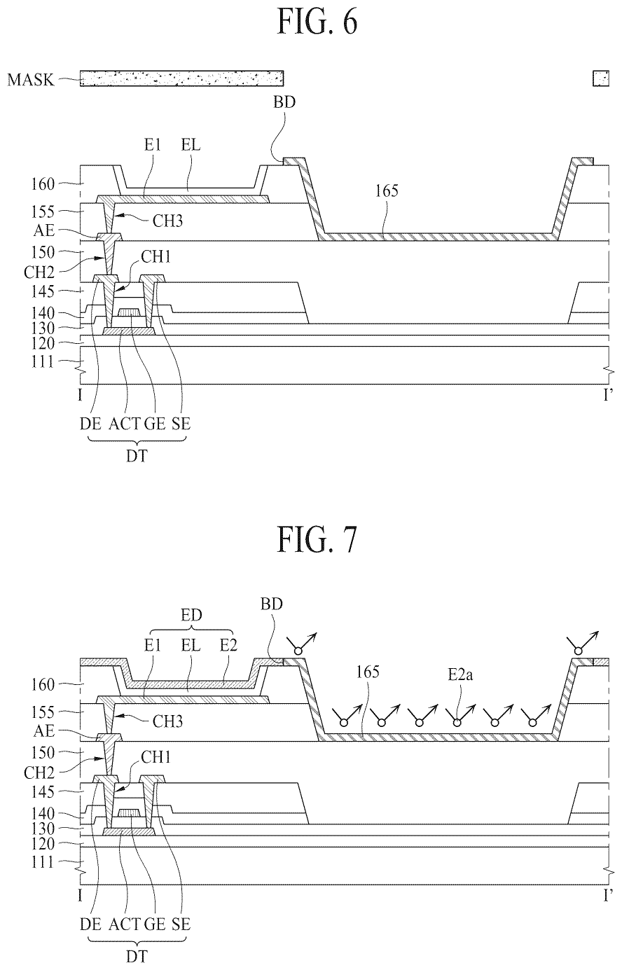

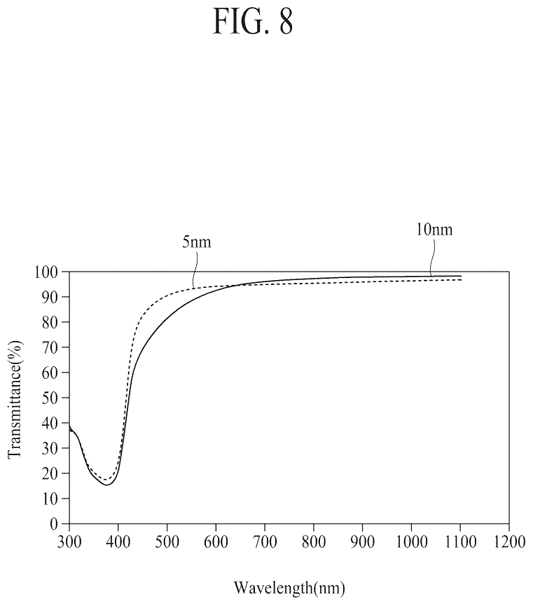

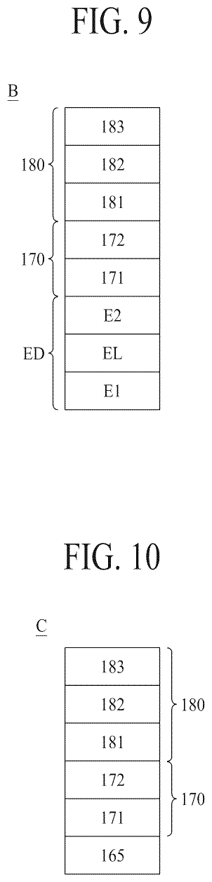

FIG. 4 is a cross-sectional view illustrating an example taken along line I-I′ illustrated in FIG. 2, FIG. 5 is a plan view illustrating an example of a second electrode of a light emitting device and an organic pattern layer according to aspects of the present disclosure, FIG. 6 is a cross-sectional view illustrating an example of a method for forming the organic pattern layer according to aspects of the present disclosure, FIG. 7 is a cross-sectional view illustrating an example of a method for forming the second electrode of the light emitting device according to aspects of the present disclosure, FIG. 8 is a graph for illustrating light transmittance of the organic pattern layer according to aspects of the present disclosure, FIG. 9 illustrates a stacked structure according to one example of a region B of FIG. 4, and FIG. 10 illustrates a stacked structure according to one example of a region C of FIG. 4.

Referring to FIG. 4, the transparent display panel 110 according to one or more examples of the present disclosure includes a first substrate 111 and a second substrate 112 facing each other. A circuit element, the light emitting device ED, an organic pattern layer 165, an encapsulation layer 180, a color filter CF, and a black matrix BM can be disposed between the first substrate 111 and the second substrate 112.

The circuit element is disposed for each of the subpixels SP1, SP2, and SP3. The circuit element can include various signal lines, thin-film transistor, and capacitor, etc. The signal lines can include the gate lines, the data lines, driving power lines, etc. The thin film transistor can include the switching transistor ST and the driving transistor DT. The switching transistor ST can be switched according to the scan signal supplied to the gate line to charge the capacitor Cst with the data voltage supplied from the data line.

The driving transistor DT can be switched according to the data voltage charged in the capacitor Cst, generates the data current from the driving voltage EVDD supplied from the first power line PL1, and supplies the data current to the first electrode E1 of each of the subpixels SP1, SP2, and SP3. The driving transistor DT can include an active layer ACT, a gate electrode GE, a source electrode SE, and a drain electrode DE.

Specifically, as illustrated in FIG. 4, a buffer layer 120 can be disposed on the first substrate 111. The buffer layer 120 can protect the driving transistor DT from moisture penetrating through the first substrate 111 that is vulnerable to moisture permeation. To this end, the buffer layer 120 can be disposed in the non-transmissive area NTA and the transmissive area TA. The buffer layer 120 can be formed of an inorganic layer, for example, a silicon oxide layer SiOx, a silicon nitride layer SiNx, or multiple layers thereof.

Although not shown in FIG. 4, a light blocking layer can be further disposed between the first substrate 111 and the buffer layer 120. The light blocking layer can serve to block external light incident onto the active layer ACT in the region in which the driving transistor DT is formed. The light blocking layer can be formed as a single layer or multiple layers made of any one of or an alloy of molybdenum Mo, aluminum Al, chromium Cr, gold Au, titanium Ti, nickel Ni, neodymium Nd, and copper Cu. The light blocking layer can be omitted.

The active layer ACT of the driving transistor DT can be disposed on the buffer layer 120. The active layer ACT of the driving transistor DT can be formed of a silicon-based semiconductor material or an oxide-based semiconductor material.

A gate insulating layer 130 can be disposed on the active layer ACT of the driving transistor DT. The gate insulating layer 130 can be disposed in the non-transmissive area NTA and the transmissive area TA. The gate insulating layer 130 can be formed of an inorganic layer, for example, a silicon oxide layer SiOx, a silicon nitride layer SiNx, or multiple layers thereof.

The gate electrode GE of the driving transistor DT can be disposed on the gate insulating layer 130. The gate electrode GE of the driving transistor DT can be formed as a single layer or multiple layers made of any one or an alloy of molybdenum Mo, aluminum Al, chromium Cr, gold Au, titanium Ti, nickel Ni, neodymium Nd, and copper Cu.

A first interlayer insulating layer 140 and a second interlayer insulating layer 145 can be disposed on the gate electrode GE of the driving transistor DT. In order to increase the light transmittance of the transmissive area TA, the first interlayer insulating layer 140 and the second interlayer insulating layer 145 can be disposed only in the non-transmissive area NTA, and cannot be disposed in the transmissive area TA. Each of the first interlayer insulating layer 140 and the second interlayer insulating layer 145 can be formed of an inorganic layer, for example, a silicon oxide layer SiOx, a silicon nitride layer SiNx, or multiple layers thereof.

The source electrode SE and the drain electrode DE of the driving transistor DT can be disposed on the second interlayer insulating layer 145. Each of the source electrode SE and the drain electrode DE of the driving transistor DT can be connected to the active layer ACT of the driving transistor DT through a first contact hole CH1 penetrating the gate insulating layer 130, the first interlayer insulating layer 140, and the second interlayer insulating layer 145. The source electrode SE and the drain electrode DE of the driving transistor DT can be formed as a single layer or multiple layers made of any one or an alloy of molybdenum Mo, aluminum Al, chromium Cr, gold Au, titanium Ti, nickel Ni, neodymium Nd, and copper Cu.

A first planarization layer 150 can be disposed on the source electrode SE and the drain electrode DE of the driving transistor DT to planarize the step difference caused by the driving transistor DT. The first planarization layer 150 can be formed of an organic layer such as an acrylic resin, an epoxy resin, a phenolic resin, a polyamide resin, or a polyimide resin.

An auxiliary electrode AE can be disposed on the first planarization layer 150. The auxiliary electrode AE can be connected to one of the source electrode SE and the drain electrode DE of the driving transistor DT through a second contact hole CH2 penetrating the first planarization layer 150. The auxiliary electrode AE can be formed as a single layer or multiple layers made of any one or an alloy of molybdenum Mo, aluminum Al, chromium Cr, gold Au, titanium Ti, nickel Ni, neodymium Nd, and copper Cu.

A second planarization layer 155 can be formed on the auxiliary electrode AE. The second planarization layer 155 can be formed of an organic film such as an acrylic resin, an epoxy resin, a phenolic resin, a polyamide resin, or a polyimide resin.

At least one of the first planarization layer 150 and the second planarization layer 155 can be disposed in the non-transmissive area NTA and cannot be disposed in at least a part of the transmissive area TA.

In one or more embodiments, the second planarization layer 155 can include a first opening area OA1 overlapping at least a portion of the transmissive area TA as shown in FIG. 4. For example, the first opening area OA1 of the second planarization layer 155 can be formed to have a size larger than that of the transmissive area TA. In this example, the first opening area OA1 of the second planarization layer 155 can overlap all areas of the transmissive area TA. The second planarization layer 155 can include an upper surface Sla which is flat and an inclined surface S1b exposed by the first opening area OA1. The upper surface Sla and the inclined surface S1b of the second planarization layer 155 can be disposed in the non-transmissive area NTA.

Although FIG. 4 illustrates that the first opening area OA1 is disposed only in the second planarization layer 155, the present disclosure is not limited thereto. In another embodiment, the first opening area OA1 can be disposed in each of the first planarization layer 150 and the second planarization layer 155.

In the transparent display panel 110 according to the one example of the present disclosure, at least one of the first planarization layer 150 and the second planarization layer 155 cannot be disposed in the transmissive area TA, thereby improving the light transmittance of the transmissive area TA.

The light emitting device ED and a bank 160 can be disposed on the second planarization layer 155. The light emitting device ED can include a first electrode E1, a light emitting layer EL, and a second electrode E2.

The first electrode E1 can be disposed on the second planarization layer 155 and can be electrically connected to the driving transistor DT. In detail, the first electrode E1 can be connected to the auxiliary electrode AE through a third contact hole CH3 penetrating the second planarization layer 155. Since the auxiliary electrode AE is connected to one of the source electrode SE and the drain electrode DE of the driving transistor DT through the second contact hole CH2, the first electrode E1 can be connected to one of the source electrode SE and the drain electrode DE of the driving transistor DT through the auxiliary electrode AE.

The first electrode E1 can be disposed for each of the subpixels SP1, SP2, and SP3, and cannot be disposed in the transmissive area TA. The bank 160 can be disposed between the first electrodes E1 adjacent to each other, and thus the first electrodes E1 adjacent to each other can be electrically insulated from each other.

The first electrode E1 can be formed of a highly reflective metal material such as a stacked structure of aluminum and titanium (Ti/Al/Ti), a stacked structure of aluminum and ITO (ITO/AI/ITO), an Ag alloy, a stacked structure of Ag alloy and ITO (ITO/Ag alloy/ITO), a MoTi alloy, and a stacked structure of the MoTi alloy and ITO (ITO/MoTi alloy/ITO). The Ag alloy can be an alloy such as an alloy of silver Ag, palladium Pd, copper Cu, etc. The MoTi alloy can be an alloy of molybdenum Mo and titanium Ti. The first electrode E1 can be an anode electrode.

The bank 160 can be disposed on the second planarization layer 155. The bank 160 can be formed to cover an edge of the first electrode E1 and expose a part of the first electrode E1. Accordingly, the bank 160 can prevent a problem in which the light emission efficiency is deteriorated due to the concentration of current on the end of the first electrode E1.

The bank 160 can define emission areas EA1, EA2 and EA3 of each of the subpixels SP1, SP2, and SP3. The emission areas EA1, EA2, and EA3 of each of the subpixels SP1, SP2, and SP3 can indicate areas in which holes from the first electrode E1 and electrons from the second electrode E2 are coupled to each other in the light emitting layer EL to emit light. In this example, an area in which the bank 160 is disposed does not emit light and thus becomes the non-emission area NEA, and an area in which the bank 160 is not disposed and the first electrode E1 is exposed can be the emission areas EA1, EA2, and EA3.

As shown in FIG. 4, the bank 160 can be disposed in the non-transmissive area NTA, and cannot be disposed in at least a portion of the transmissive area TA. For example, the bank 160 can include a second opening area OA2 overlapping at least a portion of the transmissive area TA. For example, the second opening area OA2 of the bank 160 can be formed to have a size larger than that of the transmissive area TA. In this example, the second opening area OA2 of the bank 160 can overlap all areas of the transmissive area TA. The second opening area OA2 of the bank 160 can be formed to have a size larger than that of the first opening area OA1 of the second planarization layer 155. The second opening area OA2 of the bank 160 can overlap all areas of the first opening area OA1 of the second planarization layer 155.

The bank 160 can include an upper surface S2a which is flat and an inclined surface S2b exposed by the second opening area OA2. The upper surface S2a and the inclined surface S2b of the bank 160 can be disposed in the non-transmissive area NTA.

The bank 160 can be formed of an organic layer such as an acryl-based material, an epoxy-based material, a phenolic-based material, a polyamide-based material, and a polyimide-based material, etc.

The light emitting layer EL can be disposed on the first electrode E1. The light emitting layer EL can include an emission material layer EML including a light emitting material. The light emitting material can include an organic material, an inorganic material, or a hybrid material. The light emitting layer EL can have a multilayer structure. For example, the light emitting layer EL can further include at least one of a hole injection layer HIL, a hole transport layer HTL, an electron transport layer ETL, and an electron injection layer EIL. In this example, when a voltage is applied to the first electrode E1 and the second electrode E2, holes and electrons move to the emission material layer EML through the hole transport layer HTL and the electron transport layer ETL, respectively, and combines with each other in the emission material layer EML to emit light.

In one or more embodiments, the light emitting layer EL can be a common layer commonly formed in the subpixels SP1, SP2, and SP3. In this example, the light emitting layer EL can be a white light emitting layer emitting white light. In this example, the light emitting layer EL can be formed not only in the subpixels SP1, SP2, and SP3, but also in the non-emission area NEA between the subpixels SP1, SP2, and SP3. The light emitting layer EL can be continuously formed between the subpixels SP1, SP2, and SP3. The light emitting layer EL can be disposed in the transmissive area TA as well as the non-transmissive area NTA including the emission areas EA1, EA2, and EA3 and the non-emission area NEA, but it is not limited thereto. The light emitting layer EL can be patterned only in the non-transmissive area NTA including the emission areas EA1, EA2, and EA3 and the non-emission area NEA.

In another example embodiment, the emission material layer EML of the light emitting layer EL can be formed for each of the subpixels SP1, SP2, and SP3. For example, a green light emitting layer emitting green light can be formed in the first subpixel SP1, a red light emitting layer emitting red light can be formed in the second subpixel SP2, and a blue light emitting layer emitting blue light can be formed in the third subpixel SP3. In this example, the emission material layer EML of the light emitting layer EL cannot be formed in the transmissive area TA. However, the hole injection layer HIL, the hole transport layer HTL, the electron transport layer ETL, and the electron injection layer EIL except for the emission material layer EML can be formed in common in the subpixels SP1, SP2, and SP3, and can also be formed in the transmissive area TA.

The second electrode E2 can be disposed on the light emitting layer EL. The second electrode E2 can be a common layer commonly formed in the subpixels SP1, SP2, and SP3. The second electrode E2 can be formed not only in the emission areas EA1, EA2, and EA3 of the subpixels SP1, SP2, and SP3, but also in the non-emission area NEA between the subpixels SP1, SP2, and SP3. The second electrode E2 can be continuously formed between the subpixels SP1, SP2, and SP3.

As shown in FIG. 4, the second electrode E2 can be disposed in the non-transmissive area NTA, and cannot be disposed in at least a portion of the transmissive area TA. For example, the second electrode E2 can include a third opening area OA3 overlapping at least a portion of the transmissive area TA.

The third opening area OA3 of the second electrode E2 can be formed to be larger than the transmissive area TA. In this example, the third opening area OA3 of the second electrode E2 can overlap all areas of the transmissive area TA. The third opening area OA3 of the second electrode E2 can be formed to be larger than the first opening area OA1 of the second planarization layer 155, and can overlap all areas of the first opening area OA1 of the second planarization layer 155. In this example, the third opening area OA3 of the second electrode E2 can also overlap with an area in which the inclined surface S1b of the second planarization layer 155 is disposed.

The third opening area OA3 of the second electrode E2 can be formed to be larger than the second opening area OA2 of the bank 160, and can overlap all areas of the second opening area OA2 of the bank 160. In this example, the third opening area OA3 of the second electrode E2 can also overlap with an area in which the inclined surface S2b of the bank 160 is disposed.

The second electrode E2 can be formed of a transparent metal material TCO (Transparent Conductive Oxide) such as ITO or IZO capable of transmitting light, or a semi-transmissive conductive material such as magnesium Mg, silver Ag, or an alloy of magnesium Mg and silver Ag. When the second electrode E2 is formed of the semi-transmissive conductive material, light emission efficiency can be increased due to a micro cavity. The second electrode E2 can be a cathode electrode.

The organic pattern layer 165 can be disposed in the transmissive area TA. At least a portion of the organic pattern layer 165 can be disposed on the same layer as the second electrode E2, and can be disposed in the third opening area OA3 of the second electrode E2. An edge of the organic pattern layer 165 can be in contact with the second electrode E2 within the third opening area OA3 of the second electrode E2. The organic pattern layer 165 can be in contact with the second electrode E2 along the side surface of it.

The second electrode E2 cannot be deposited on the organic pattern layer 165 due to the characteristics of the material. For example, the organic pattern layer 165 does not overlap the second electrode E2. Specifically, the second electrode E2 can include a first material having conductivity. The organic pattern layer 165 can include a second material from which the first material is desorbed. The second material forming the organic pattern layer 165 can be an organic material having low surface energy of the material itself or high interfacial energy between the metal materials. The second material having such characteristics has a low deposition rate of the metal material due to desorption of the metal material on the surface during deposition of the metal material.

The second material forming the organic pattern layer 165 can have high light transmittance. The second material forming the organic pattern layer 165 can have high light transmittance in the visible light wavelength band as shown in FIG. 8. For example, the organic pattern layer 165 can have higher light transmittance than that of the second electrode E2.

The transparent display panel 110 according to one example embodiment of the present disclosure can selectively pattern the second electrode E2 by using the characteristics of the second material forming the organic pattern layer 165.

First, as shown in FIG. 6, a mask having an opening area corresponding to the transmissive area TA can be disposed on the first substrate 111. By depositing a second material forming the organic pattern layer 165 on the first substrate 111 on which the mask is disposed, the organic pattern layer 165 can be patterned in the transmissive area TA.

Next, as shown in FIG. 7, after the mask is removed, the first material E2a forming the second electrode E2 can be entirely deposited. In this example, the first material E2a can be deposited in an area where the organic pattern layer 165 is not disposed to form the second electrode E2. On the other hand, the first material E2a can be desorbed and cannot be deposited in an area where the organic pattern layer 165 is disposed. Accordingly, the second electrode E2 cannot be formed in the area where the organic pattern layer 165 is disposed, and thus the third opening area OA3 can be formed. The second electrode E2 can be in contact with the edge of the organic pattern layer 165 in the third opening area OA3.

As shown in FIG. 5, the organic pattern layer 165 can be in contact with the second electrode E2 in the non-transmissive area NTA. A border BD between the second electrode E2 and the organic pattern layer 165 can be disposed in the non-transmissive area NTA. The border BD between the second electrode E2 and the organic pattern layer 165 can be disposed along an edge of the non-transmissive area NTA in the non-transmissive area NTA.

Specifically, the border BD between the second electrode E2 and the organic pattern layer 165 can be disposed on the upper surface Sla of the second planarization layer 155 and the flat upper surface S2a of the bank 160.

For example, the border BD between the second electrode E2 and the organic pattern layer 165 can be disposed on the flat upper surface S2a of the bank 160 as shown in FIG. 4. For example, the end of the second electrode E2 and the end of the organic pattern layer 165 can be in contact with at least a portion of the upper surface S2a of the bank 160.

The border BD between the second electrode E2 and the organic pattern layer 165 can be disposed in the non-emission area NEA including the bank 160. The end of the second electrode E2 and the end of the organic pattern layer 165 can be disposed on a flat surface such as the upper surface Sla of the second planarization layer 155 and the upper surface S2a of the bank 160.

Since the second electrode E2 and the organic pattern layer 165 are made of different materials, light can be refracted or reflected at the border BD between the second electrode E2 and the organic pattern layer 165 and changes its the propagation direction. Moreover, when a step difference occurs between the second electrode E2 and the organic pattern layer 165, which are made of different materials, the fluctuation of light along the step difference plane can be further increased.

In the transparent display panel 110 according to one example embodiment of the present disclosure, since the border BD between the second electrode E2 and the organic pattern layer 165 can be disposed in the non-emission area NEA, light emitted from the light emitting layer EL of the light emitting device ED or light incident from the outside can be prevented from being refracted or reflected at the border BD between the second electrode E2 and the organic pattern layer 165. Accordingly, the transparent display panel 110 according to one example embodiment of the present disclosure can prevent the occurrence of a light leakage phenomenon in which light emitted from the light emitting layer EL of the light emitting device ED is emitted into the transmissive area TA or other subpixel area.

In the transparent display panel 110 according to one example embodiment of the present disclosure, an end of the second electrode E2 and an end of the organic pattern layer 165 can be disposed on a flat surface. In the process of depositing a material to form a pattern, the material can be deposited to have a constant thickness on the flat surface rather than on an inclined surface. The material cannot be formed with a constant thickness on the inclined surface and can be deposited thinner than on the flat surface. In particular, when an end of the pattern is formed on the inclined surface, the thickness of the end of the pattern can be formed with an inconstant thickness. Accordingly, In the process, it is not easy to control the thickness of the material on the inclined surface.

In the transparent display panel 110 according to the one example embodiment of the present disclosure, the end of the organic pattern layer 165 can be formed on the flat surface such as the upper surface S2a of the bank 160, so that the end of the organic pattern layer 165 can have a desired thickness.

In one example embodiment, the organic pattern layer 165 and the second electrode E2 can have the same thickness on the upper surface S2a of the bank 160. The surface S3 of the second electrode E2 can be formed at the same height as the upper surface S4 of the organic pattern layer 165. Since the upper surface S3 of the second electrode E2 and the upper surface S4 of the organic pattern layer 165 do not have a step difference, the second electrode E2 and the organic pattern layer 165 can have flat surfaces at the border BD. For example, a flat surface FS including the upper surface S3 of the second electrode E2 and the upper surface S4 of the organic pattern layer 165 can be provided.

Thus, in the transparent display panel 110 according to one example embodiment of the present disclosure, since there is no a step difference at the border BD between the second electrode E2 and the organic pattern layer 165, the light emitted from the light emitting layer EL of the light emitting device ED or the light incident from the outside can be prevented from being refracted or reflected at the border BD between the second electrode E2 and the organic pattern layer 165.

On the other hand, the border BD between the second electrode E2 and the organic pattern layer 165 is not disposed on the inclined surface S1b of the second planarization layer 155 and the inclined surface S2b of the bank 160. In other words, the border BD between the second electrode E2 and the organic pattern layer 165 can be spaced apart from the inclined surface S1b of the second planarization layer 155 in a plan view. Further, the border BD between the second electrode E2 and the organic pattern layer 165 can be spaced apart from the inclined surface S2b of the bank 160 in a plan view.

When the material forming the organic pattern layer 165 is deposited so that the end of the organic pattern layer 165 is formed on the inclined surface S1b of the second planarization layer 155 or the inclined surface S2b of the bank 160, the material forming the organic pattern layer 165 cannot have a thickness designed on the inclined surface S1b of the second planarization layer 155 or the inclined surface S2b of the bank 160 and can be formed to be thinner.

Then, when the material forming the second electrode E2 is deposited, the second electrode E2 can be deposited in an area where the organic pattern layer 165 is not formed. In this case, the end of the second electrode E2 is formed on the inclined surface S1b of the second planarization layer 155 or the inclined surface S2b of the bank 160, and the end of the second electrode E2 can also not have a designed thickness. In this way, the ends of each of the organic pattern layer 165 and the second electrode E2 do not have a designed thickness and can be deposited to have different thicknesses. In this case, a step difference can occur at the border BD at which the end of the organic pattern layer 165 is in contact with the end of the second electrode E2, and thus, the propagation direction of light incident from the outside can be greatly changed at the border BD between the second electrode E2 and the organic pattern layer 165.

Particularly, since the inclined surface S1b of the second planarization layer 155 or the inclined surface S2b of the bank 160 provides a passage through which the external light incident to the transmissive area TA passes, a large amount of external light can be incident. When the external light is refracted or reflected at the border BD between the second electrode E2 and the organic pattern layer 165 disposed on the inclined surface S1b of the second planarization layer 155 or the inclined surface S2b of the bank 160, an object located on the rear surface of the transparent display panel 110 can appear distorted or blurred, which can cause the Mura phenomenon.

To prevent this, the transparent display panel 110 according to one example embodiment of the present disclosure can be designed such that the border BD between the second electrode E2 and the organic pattern layer 165 is not disposed on the inclined surface S1b of the second planarization layer 155 and the inclined surface S2b of the bank 160.

The encapsulation layer 180 can be disposed on the light emitting device ED and the organic pattern layer 165. The encapsulation layer 180 can be formed on the second electrode E2 and the organic pattern layer 165 to cover the second electrode E2 and the organic pattern layer 165. The encapsulation layer 180 serves to prevent oxygen or moisture from penetrating into the light emitting layer EL, the second electrode E2, and the organic pattern layer 165. To this end, the encapsulation layer 180 can include at least one inorganic layer and at least one organic layer. The encapsulation layer 180 can have a structure in which an inorganic layer and an organic layer are alternately stacked, but it is not limited thereto.

For example, as illustrated in FIG. 9 and FIG. 10, the encapsulation layer 180 can have a structure in which a first inorganic layer 181, an organic layer 182, and a second inorganic layer 183 are stacked. The first inorganic layer 181 can be formed to cover the second electrode E2 and the organic pattern layer 165. The organic layer 182 can be formed on the first inorganic layer 181 to have a sufficient thickness to prevent particles from penetrating the first inorganic layer 181 and entering the light emitting layer EL, the second electrode E2, and the organic pattern layer 165. The second inorganic layer 183 can be formed to cover the organic layer 182.

A capping layer 170 can be further disposed between the encapsulation layer 180 and the light emitting device ED, and between the encapsulation layer 180 and the organic pattern layer 165. The capping layer 170 can be disposed to cover the second electrode E2 on the second electrode E2, thereby improving viewing angle characteristics and increasing external light emission efficiency. The capping layer 170 can include at least one of an inorganic layer and an organic layer, which have light transmittance, and can have a single layer structure or a multilayer structure. The capping layer 170 can have a structure in which a first inorganic layer 171 and a second inorganic layer 172 are stacked.

A color filter CF can be disposed on the encapsulation layer 180. The color filter CF can be patterned for each of the subpixels SP1, SP2, and SP3. Specifically, the color filter CF can include a first color filter, a second color filter, and a third color filter. The first color filter can be disposed to correspond to the emission area EA1 of the first subpixel SP1, and can be a green color filter that transmits green light. The second color filter can be disposed to correspond to the emission area EA2 of the second subpixel SP2, and can be a red color filter that transmits red light. The third color filter can be disposed to correspond to the emission area EA3 of the third subpixel SP3, and can be a blue color filter that transmits blue light.

The transparent display panel 110 according to one example embodiment of the present disclosure can include the color filter CF without using a polarizing plate. When the polarizing plate is attached to the transparent display panel 110, the transmittance of the transparent display panel 110 can decrease due to the polarizing plate. On the other hand, when the polarizing plate is not attached to the transparent display panel 110, a problem can occur where the light incident from the outside is reflected by electrodes.

In the transparent display panel 110 according to one example embodiment of the present disclosure, since the polarizing plate is not attached, a decrease in transmittance can be prevented. In addition, in the transparent display panel 110 according to one example embodiment of the present disclosure, since the color filter CF is formed, the color filter CF can absorb a part of the light incident from the outside so that the light incident from the outside can be prevented from being reflected by the electrodes. For example, the transparent display panel 110 according to one example embodiment of the present disclosure can reduce the external light reflectance without reducing transmittance.

A black matrix BM can be disposed between the color filters CF patterned for each of the subpixels SP1, SP2, and SP3. The black matrix BM can be disposed between the subpixels SP1, SP2, and SP3 to prevent color mixture from being generated between adjacent subpixels SP1, SP2, and SP3. Further, the black matrix BM can prevent light incident from the outside from being reflected by a plurality of signal lines disposed between the subpixels SP1, SP2, and SP3.

The black matrix BM can be disposed between the transmissive area TA and a plurality of subpixels SP1, SP2, and SP3, and can prevent light emitted from each of a plurality of subpixels SP1, SP2, and SP3 from being propagated to the transmissive area TA. Accordingly, the black matrix BM can define a border between the transmissive area TA and the non-transmissive area NTA. In detail, the black matrix BM can define the border between the non-transmissive area NTA and the transmissive area TA between the emission area EA and the transmissive area TA. In this example, in an area other than the emission area EA, an area in which the black matrix BM is disposed can be the non-transmissive area NTA, and an area in which the black matrix BM is not disposed can be the transmissive area TA. For example, an area in which the emission area EA and the black matrix BM are disposed can be the non-transmissive area NTA, and the remaining area can be the transmissive area TA.

The black matrix BM can be disposed to cover an area in which the bank 160 is disposed. The black matrix BM can be disposed to cover not only the upper surface S2a but also the inclined surface S2b of the bank 160. Furthermore, the black matrix BM can be disposed to cover the inclined surface S1b of the second planarization layer 155.

In the transparent display panel 110 according to one example embodiment of the present disclosure, the border BD between the second electrode E2 and the organic pattern layer 165 can be disposed to overlap the black matrix BM. Specifically, the border BD between the second electrode E2 and the organic pattern layer 165 can be disposed to overlap the black matrix BM disposed between the pixel P and the transmissive area TA. Accordingly, in the transparent display panel 110 according to one example embodiment of the present disclosure, even though light emitted from the light emitting layer EL of the light emitting device ED or light incident from the outside is refracted or reflected at the border BD between the second electrode E2 and the organic pattern layer 165, the refracted or reflected light can be absorbed by the black matrix BM. The transparent display panel 110 according to one example embodiment of the present disclosure can prevent light emitted from the light emitting layer EL of the light emitting device ED from being emitted to the transmissive area TA or another subpixel area.

The black matrix BM can include a material that absorbs light, for example, a black dye that absorbs all light in the visible wavelength band.

The color filter CF and the black matrix BM are not disposed in the transmissive area TA to maintain a high light transmittance in the transmissive area TA.

The color filter CF and the black matrix BM can be directly formed on the first substrate 111 having the encapsulation layer 180. For example, the color filter CF and the black matrix BM can be formed to be in contact with an upper surface of the encapsulation layer 180. In another example, when an additional layer is further disposed on the encapsulation layer 180, the color filter CF and the black matrix BM can be directly formed on the additional layer disposed on the encapsulation layer 180.

When the color filter CF and the black matrix BM are directly formed on the first substrate 111 with the encapsulation layer 180, a process error can be reduced. When the color filter CF and the black matrix BM are formed on the second substrate 112 and are bonded to the first substrate 111 with the encapsulation layer 180, a relatively large error can occur during bonding, and in this case, the color filter CF and the black matrix BM cannot be disposed at a desired position.

Accordingly, the border BD between the second electrode E2 and the organic pattern layer 165 cannot overlap the black matrix BM. In this case, when the border BD between the second electrode E2 and the organic pattern layer 165 is disposed to overlap the color filter CF, the light emitted from the light emitting layer EL can be refracted or reflected at the border BD between the second electrode E2 and the organic pattern layer 165 to reduce light efficiency or move to an adjacent subpixel area, thereby causing a light leakage phenomenon. Alternatively, when the border BD between the second electrode E2 and the organic pattern layer 165 is disposed to overlap the transmissive area TA, the light incident from the outside can be refracted or reflected at the border BD between the second electrode E2 and the organic pattern layer 165 to distort an object or cause Mura phenomenon.

In order to ensure that the border BD between the second electrode E2 and the organic pattern layer 165 overlaps the black matrix BM, an area of the black matrix BM can be formed large in consideration of a bonding margin between the first substrate 111 and the second substrate 112. However, when the area of the black matrix BM increases, the area of the non-transmissive area NTA increases, and thus the area of the transmissive area TA can decrease. Accordingly, the light transmittance of the transparent display panel 110 can decrease.

In the transparent display panel 110 according to one example embodiment of the present disclosure, the color filter CF and the black matrix BM are directly formed on the first substrate 111 with the encapsulation layer 180, thereby reducing a process error that can occur and allowing the color filter CF and the black matrix BM to be disposed within a desired area. Accordingly, the transparent display panel 110 according to one example embodiment of the present disclosure can ensure that the border BD between the second electrode E2 and the organic pattern layer 165 overlaps the black matrix BM without increasing the area of the black matrix BM.

The first substrate 111 including the color filter CF and the black matrix BM can be bonded to the second substrate 112 by a separate adhesive layer 190. In this example, the adhesive layer 190 can be an optically clear resin layer OCR or an optically clear adhesive film OCA.

In the transparent display panel 110 according to one example embodiment of the present disclosure, the second electrode E2 is not disposed in the transmissive area TA, thereby improving light transmittance of the transmissive area TA.

Furthermore, in the transparent display panel 110 according to one example embodiment of the present disclosure, the organic pattern layer 165 can be disposed in the transmissive area TA, and the second electrode E2 can be patterned not to be deposited in the transmissive area TA by using properties of a material forming the organic pattern layer 165. The transparent display panel 110 according to one example embodiment of the present disclosure can pattern the second electrode E2 through a simple process.

Furthermore, in the transparent display panel 110 according to one example embodiment of the present disclosure, since the border BD between the second electrode E2 and the organic pattern layer 165 can be disposed in the non-emission area NEA, the light emitted from the light emitting layer EL of the light emitting device ED can be prevented from being refracted or reflected at the border BD between the second electrode E2 and the organic pattern layer 165. Accordingly, in the transparent display panel 110 according to one example embodiment of the present disclosure, a light leakage phenomenon in which the light emitted from the light emitting layer EL of the light emitting device ED is emitted to the transmissive area TA or another subpixel area can be prevented from being occurred.

Furthermore, in the transparent display panel 110 according to one example embodiment of the present disclosure, since an end of the organic pattern layer 165 is formed on a flat surface, a step difference cannot occur at the border BD between the second electrode E2 and the organic pattern layer 165. Accordingly, in the transparent display panel 110 according to one example embodiment of the present disclosure, the light emitted from the light emitting layer EL of the light emitting device ED or the light incident from the outside can be prevented from being largely refracted or reflected along the step difference plane at the border BD between the second electrode E2 and the organic pattern layer 165.

In addition, since the border BD between the second electrode E2 and the organic pattern layer 165 is not disposed on the inclined surface S1b of the second planarization layer 155 or the inclined surface S2b of the bank 160, it is possible to prevent the occurrence of Mura phenomenon in which an object located on rear surface of the transparent display panel 110 appears distorted or blurred.

Furthermore, in the transparent display panel 110 according to one example embodiment of the present disclosure, since the border BD between the second electrode E2 and the organic pattern layer 165 is disposed to overlap with the black matrix BM, even if a portion of the light emitted from the light emitting layer EL of the light emitting device ED or a portion of the light incident from the outside is refracted or reflected at the border BD between the second electrode E2 and the organic pattern layer 165, the refracted or reflected light can be absorbed in the black matrix BM. Thus, in the transparent display panel 110 according to one example embodiment of the present disclosure, the light emitted from the light emitting layer EL of the light emitting device ED can be prevented from being emitted to the transmissive area TA or another subpixel area.

Furthermore, in the transparent display panel 110 according to one example embodiment of the present disclosure, since the Mura defects and light leakage defects cannot be occurred, the defect rate of the product can be reduced, the manufacturing process cost can be reduced, the manufacturing process time can be shortened, and the production energy can be reduced. Further, in the transparent display panel 110 according to one example embodiment of the present disclosure, the generation of greenhouse gases due to the manufacturing process can be reduced, thereby implementing ESG (Environment/Social/Governance).

In addition, in the transparent display panel 110 according to one example embodiment of the present disclosure, the color filter CF and the black matrix BM are directly formed on the first substrate 111 with the encapsulation layer 180, thereby reducing process errors that can occur and ensuring that the border BD between the second electrode E2 and the organic pattern layer 165 overlaps with the black matrix BM without increasing the area of the black matrix BM.

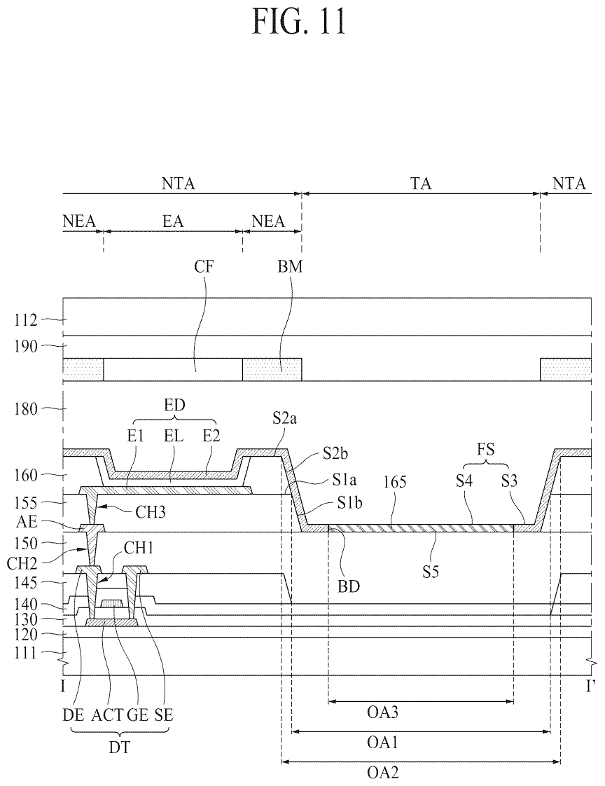

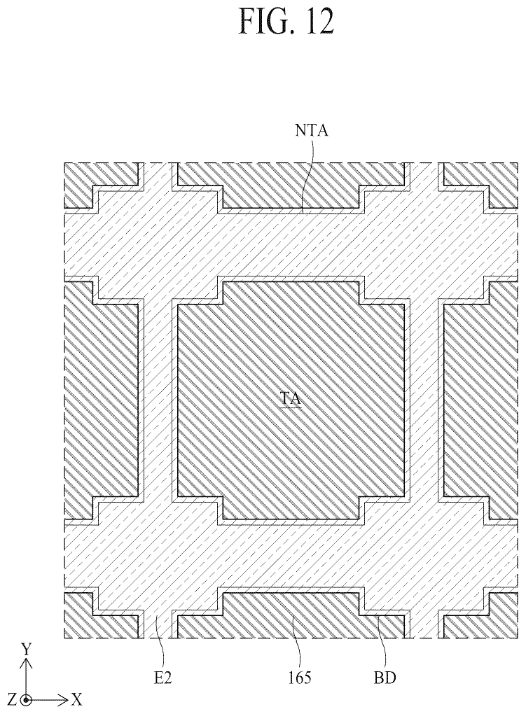

FIG. 11 is a cross-sectional illustrating another example taken along line I-I′ illustrated in FIG. 2 and FIG. 12 is a plan view illustrating another example of a second electrode of a light emitting device and an organic pattern layer according to aspects of the present disclosure.

Referring to FIGS. 11 and 12, the transparent display panel 110 according to another embodiment of the present disclosure can includes a first substrate 111 and a second substrate 112 facing each other. A circuit element, the light emitting device ED, an organic pattern layer 165, an encapsulation layer 180, a color filter CF, and a black matrix BM can be disposed between the first substrate 111 and the second substrate 112.

The transparent display panel 110 illustrated in FIGS. 11 and 12 is substantially the same as the transparent display panel 110 illustrated in FIGS. 4 to 10, except for the second electrode E2 of the light emitting device ED and the organic pattern layer 165. Hereinafter, the second electrode E2 of the light emitting device ED and the organic pattern layer 165 will be mainly described with respect to the differences, and the descriptions of the substantially identical components will be omitted.

As shown in FIG. 11, the second electrode E2 of the light emitting device ED can be disposed in the non-transmissive area NTA and at least a portion of the transmissive area TA, and cannot be disposed in another portion of the transmissive area TA. For example, the second electrode E2 can include a third opening area OA3 overlapping at least a portion of the transmissive area TA.

The third opening area OA3 of the second electrode E2 can be formed to be smaller than the transmissive area TA. Further, the third opening area OA3 of the second electrode E2 can be formed to be smaller than the first opening area OA1 of the second planarization layer 155. In this example, the second electrode E2 can overlap with an area on which the inclined surface S1b of the second planarization layer 155 is disposed.

The third opening area OA3 of the second electrode E2 can be formed to be smaller than the second opening area OA2 of the bank 160. In this example, the second electrode E2 can overlap with an area in which the inclined surface S2b of the bank 160 is disposed.

The second electrode E2 can be formed of a transparent metal material TCO such as ITO or IZO capable of transmitting light, or a semi-transmissive conductive material such as magnesium Mg, silver Ag, or an alloy of magnesium Mg and silver Ag. When the second electrode E2 is formed of the semi-transmissive conductive material, light emission efficiency can be increased due to a micro cavity.

The organic pattern layer 165 can be disposed in at least a portion of the transmissive area TA. The organic pattern layer 165 can be disposed on the same layer as the second electrode E2, and can be disposed in the third opening area OA3 of the second electrode E2. An edge of the organic pattern layer 165 can be in contact with the second electrode E2 within the third opening area OA3 of the second electrode E2. The organic pattern layer 165 can be in contact with the second electrode E2 along the side surface of it.

The second electrode E2 cannot be deposited on the organic pattern layer 165 due to the characteristics of the material. For example, the organic pattern layer 165 does not overlap the second electrode E2. Specifically, the second electrode E2 can include a first material having conductivity. The organic pattern layer 165 can include a second material from which the first material is desorbed. The second material forming the organic pattern layer 165 can be an organic material having low surface energy of the material itself or high interfacial energy between the metal materials. The second material having such characteristics has a low deposition rate of the metal material due to desorption of the metal material on the surface during deposition of the metal material.

The second material forming the organic pattern layer 165 can have high light transmittance. The second material forming the organic pattern layer 165 can have high light transmittance in the visible light wavelength band.

The transparent display panel 110 according to one example embodiment of the present disclosure can selectively pattern the second electrode E2 by using the characteristics of the second material forming the organic pattern layer 165.

As shown in FIG. 12, the organic pattern layer 165 can be in contact with the second electrode E2 in the transmissive area TA. A border BD between the second electrode E2 and the organic pattern layer 165 can be disposed in the transmissive area TA. The border BD between the second electrode E2 and the organic pattern layer 165 can be disposed along an edge of the transmissive area TA in the transmissive area TA.

Specifically, the border BD between the second electrode E2 and the organic pattern layer 165 can be disposed on an upper surface S5 of the first planarization layer 150. The upper surface S5 of the first planarization layer 150 can be exposed in the first opening area OA1 of the second planarization layer 155. The border BD between the second electrode E2 and the organic pattern layer 165 can be directly formed on the exposed upper surface S5 of the first planarization layer 150. For example, an end of the second electrode E2 and an end of the organic pattern layer 165 can be in contact with at least a portion of the upper surface S5 of the first planarization layer 150.

The border BD between the second electrode E2 and the organic pattern layer 165 can be formed on a flat surface like the upper surface S5 of the first planarization layer 150.

Since the second electrode E2 and the organic pattern layer 165 are made of different materials, light can be refracted or reflected at the border BD between the second electrode E2 and the organic pattern layer 165 and changes its the propagation direction. Moreover, when a step difference occurs between the second electrode E2 and the organic pattern layer 165, which are made of different materials, the fluctuation of light along the step difference plane can be further increased.

In the transparent display panel 110 according to another example embodiment of the present disclosure, an end of the second electrode E2 and an end of the organic pattern layer 165 can be disposed on a flat surface. In the process of depositing a material to form a pattern, the material can be deposited to have a constant thickness on the flat surface rather than on an inclined surface. The material cannot be formed with a constant thickness on the inclined surface and can be deposited thinner than on the flat surface. In particular, when an end of the pattern is formed on the inclined surface, the thickness of the end of the pattern can be formed with an inconstant thickness. Accordingly, In the process, it is not easy to control the thickness of the material on the inclined surface.

In the transparent display panel 110 according to another example embodiment of the present disclosure, the end of the organic pattern layer 165 can be formed on the flat surface such as the upper surface S5 of the first planarization layer 150, so that the end of the organic pattern layer 165 can have a desired thickness.

In one example embodiment, the organic pattern layer 165 and the second electrode E2 can have the same thickness on the upper surface S5 of the first planarization layer 150. The upper surface S3 of the second electrode E2 can be formed at the same height as the upper surface S4 of the organic pattern layer 165. Since the upper surface S3 of the second electrode E2 and the upper surface S4 of the organic pattern layer 165 do not have a step difference, the second electrode E2 and the organic pattern layer 165 can have flat surfaces at the border BD. For example, a flat surface FS including the upper surface S3 of the second electrode E2 and the upper surface S4 of the organic pattern layer 165 can be provided.

Thus, in the transparent display panel 110 according to another example embodiment of the present disclosure, since there is no a step difference at the border BD between the second electrode E2 and the organic pattern layer 165, refraction or reflection of the light incident from outside at the border BD between the second electrode E2 and the organic pattern layer 165 can be minimized.

On the other hand, the border BD between the second electrode E2 and the organic pattern layer 165 is not disposed on the inclined surface S1b of the second planarization layer 155 and the inclined surface S2b of the bank 160. In other words, the border BD between the second electrode E2 and the organic pattern layer 165 can be spaced apart from the inclined surface S1b of the second planarization layer 155 in a plan view. Further, the border BD between the second electrode E2 and the organic pattern layer 165 can be spaced apart from the inclined surface S2b of the bank 160 in a plan view.

When the material forming the organic pattern layer 165 is deposited so that the end of the organic pattern layer 165 is formed on the inclined surface S1b of the second planarization layer 155 or the inclined surface S2b of the bank 160, the material forming the organic pattern layer 165 cannot have a thickness designed on the inclined surface S1b of the second planarization layer 155 or the inclined surface S2b of the bank 160 and can be formed to be thinner.

Then, when the material forming the second electrode E2 is deposited, the second electrode E2 can be deposited in an area where the organic pattern layer 165 is not formed. In this case, the end of the second electrode E2 is formed on the inclined surface S1b of the second planarization layer 155 or the inclined surface S2b of the bank 160, and the end of the second electrode E2 can also not have a designed thickness. In this way, the ends of each of the organic pattern layer 165 and the second electrode E2 do not have a designed thickness and can be deposited to have different thicknesses. In this case, a step difference can occur at the border BD at which the end of the organic pattern layer 165 is in contact with the end of the second electrode E2, and thus, the propagation direction of light incident from the outside can be greatly changed at the border BD between the second electrode E2 and the organic pattern layer 165.

Particularly, since the inclined surface S1b of the second planarization layer 155 or the inclined surface S2b of the bank 160 provides a passage through which the external light incident to the transmissive area TA passes, a large amount of external light can be incident. When the external light is refracted or reflected at the border BD between the second electrode E2 and the organic pattern layer 165 disposed on the inclined surface S1b of the second planarization layer 155 or the inclined surface S2b of the bank 160, an object located on the rear surface of the transparent display panel 110 can appear distorted or blurred, which can cause the Mura phenomenon.

To prevent this, the transparent display panel 110 according to another example embodiment of the present disclosure can be designed such that the border BD between the second electrode E2 and the organic pattern layer 165 is not disposed on the inclined surface S1b of the second planarization layer 155 and the inclined surface S2b of the bank 160, but can be disposed on a flat surface.

In the transparent display panel 110 according to another example embodiment of the present disclosure, an end of the organic pattern layer 165 can be prevented from being disposed on the inclined surface S1b of the second planarization layer 155 or the inclined surface S2b of the bank 160 due to the process error. The upper surface S2a of the bank 160 disposed between the pixel P and the transmissive area TA can have a small width. Even if the end of the organic pattern layer 165 is designed to be disposed on the upper surface S2a of the bank 160, the end of the organic pattern layer 165 can be disposed on the inclined surface S1b of the second planarization layer 155 or the inclined surface S2b of the bank 160 due to a process error. Alternatively, the end of the organic pattern layer 165 can be disposed in the emission areas EA1, EA2 and EA3.

In the transparent display panel 110 according to another example embodiment of the present disclosure, the end of the organic pattern layer 165 can be disposed on a flat surface provided in the transmissive area TA, thereby ensuring that the end of the organic pattern layer 165 is not disposed on the inclined surface S1b of the second planarization layer 155 or the inclined surface S2b of the bank 160 even if the process error occurs.

In the present disclosure, the second electrode can be selectively patterned in the non-transmissive area using the organic pattern layer and the second electrode cannot be formed in the transmissive area, thereby improving the light transmittance of the transmissive area.

Moreover, in the present disclosure, the light emitted from the light emitting layer can be prevented from being refracted or reflected at the border between the second electrode and the organic pattern layer since the border between the second electrode and the organic pattern layer can be disposed in the non-transmissive area, thereby preventing the light leakage phenomenon in which the light emitted from the light emitting layer is emitted into the transmissive area or other subpixel area from occurring.

Moreover, in the present disclosure, the border between the second electrode and the organic pattern layer can be disposed to overlap with the black matrix, so that even if some of the light emitted from the light emitting layer or the light incident from the outside is refracted or reflected at the border between the second electrode and the organic pattern layer, the refracted or reflected light can be absorbed by the black matrix, and thus no light leakage phenomenon can occur.

Moreover, in the present disclosure, since the end of the organic pattern layer can be formed on a flat surface, a step difference is cannot be occurred at the border between the second electrode and the organic pattern layer. Accordingly, in the present disclosure, the light emitted from the light emitting layer of the light emitting device or the light incident from the outside can be prevented from being largely refracted or reflected along the step difference plane.

Moreover, in the present disclosure, the border between the second electrode and the organic pattern layer cannot be disposed on the inclined surface of the second planarization layer or the inclined surface of the bank, thereby preventing the occurrence of the Mura phenomenon in which objects located on the rear surface of the transparent display panel appears distorted or blurry.

Moreover, in the present disclosure, by directly disposing the color filter and the black matrix on the first substrate having the encapsulation layer, it is possible to reduce process errors and ensure that the border between the second electrode and the organic pattern layer overlaps with the black matrix without increasing the area of the black matrix.

Moreover, in the present disclosure, since the Mura defects and light leakage defects cannot be occurred, the defect rate of the product can be reduced, the manufacturing process cost can be reduced, the manufacturing process time can be shortened, and the production energy can be reduced. Further, in the present disclosure, the generation of greenhouse gases due to the manufacturing process can be reduced, thereby implementing ESG (Environment/Social/Governance).

The above-described features, structures, and effects of the present disclosure are included in at least one embodiment of the present disclosure, but are not limited to only one embodiment. Furthermore, the features, structures, and effects described in at least one embodiment of the present disclosure can be implemented through combination or modification of other embodiments by those skilled in the art. Therefore, content associated with the combination and modification should be construed as being within the scope of the present disclosure.

It will be apparent to those skilled in the art that various modifications and variations can be made in the present disclosure without departing from the spirit or scope of the disclosures. Thus, it is intended that the present disclosure covers the modifications and variations of this disclosure.

The various embodiments described above can be combined to provide further embodiments. These and other changes can be made to the embodiments in light of the above-detailed description. In general, in the following claims, the terms used should not be construed to limit the claims to the specific embodiments disclosed in the disclosure and the claims, but should be construed to include all possible embodiments along with the full scope of equivalents to which such claims are entitled. Accordingly, the claims are not limited by the disclosure.

What is claimed is:

1. A transparent display device, comprising:
a first substrate including a transmissive area configured to transmit an external light and a non-transmissive area configured to not transmit the external light thereon;
a light emitting device disposed in the non-transmissive area on the first substrate to emit light; and
an organic pattern layer disposed in the transmissive area on the first substrate,
wherein the light emitting device comprises:
a first electrode disposed in an emission area;
a light emitting layer disposed on the first electrode; and
a second electrode disposed on the light emitting layer, and
wherein the second electrode is disposed in an area in which the organic pattern layer is not disposed, and the second electrode is in contact with an edge of the organic pattern layer.

2. The transparent display device of claim 1, wherein a border between the second electrode and the organic pattern layer is disposed in the non-transmissive area.

3. The transparent display device of claim 1, further comprising:
a color filter disposed on the light emitting device; and
a black matrix disposed between the color filter and the transmissive area,
wherein a border between the second electrode and the organic pattern layer overlaps with the black matrix.

4. The transparent display device of claim 1, further comprising:
a circuit element disposed between the first substrate and the light emitting device; and
a planarization layer disposed between the circuit element and the light emitting device to planarize a step difference caused by the circuit element,
wherein the planarization layer comprises a first opening area overlapping the transmissive area.

5. The transparent display device of claim 4, wherein the planarization layer comprises an upper surface and an inclined surface exposed in the first opening area, and
wherein the inclined surface of the planarization layer is disposed in the non-transmissive area.

6. The transparent display device of claim 5, wherein a border between the second electrode and the organic pattern layer is spaced apart from the inclined surface of the planarization layer.

7. The transparent display device of claim 5, wherein a border between the second electrode and the organic pattern layer is disposed on the upper surface of the planarization layer.

8. The transparent display device of claim 5, wherein a border between the second electrode and the organic pattern layer is disposed in the first opening area.

9. The transparent display device of claim 4, wherein the planarization layer comprises a first planarization layer and a second planarization layer disposed on the first planarization layer, and
wherein the first opening area is disposed in the second planarization layer.

10. The transparent display device of claim 1, further comprising a bank disposed between the first electrode and the transmissive area,
wherein the bank comprises a second opening area overlapping the transmissive area,
wherein the bank further comprises an upper surface and an inclined surface exposed in the second opening area, and
wherein the inclined surface of the bank is disposed in the non-transmissive area.

11. The transparent display device of claim 10, wherein a border between the second electrode and the organic pattern layer is spaced apart from the inclined surface of the bank.

12. The transparent display device of claim 10, wherein a border between the second electrode and the organic pattern layer is disposed on the upper surface of the bank.

13. The transparent display device of claim 1, wherein both the second electrode and the organic pattern layer have a flat surface at a border between the second electrode and the organic pattern layer.

14. The transparent display device of claim 1, further comprising:
an encapsulation layer disposed to cover the light emitting device on the light emitting device;
a color filter disposed to correspond to the light emitting device and disposed on the encapsulation layer;
a black matrix disposed between the color filter and the transmissive area;
an adhesive layer disposed on the color filter and the black matrix; and
a second substrate bonded to the color filter and the black matrix by the adhesive layer.

15. The transparent display device of claim 1, wherein the organic pattern layer comprises a second material from which a first material forming the second electrode is desorbed.

16. A transparent display device, comprising:
a transmissive area configured to transmit an external light;
an emission area configured to emit light;
a light emitting device disposed in the emission area and including a first electrode, a light emitting layer, and a second electrode;
an organic pattern layer, wherein at least a portion of the organic pattern layer is disposed on a same layer as the second electrode of the light emitting device; and
a black matric disposed to correspond to the light emitting device in the emission area,
wherein the second electrode comprises an opening area overlapping at least a portion of the transmissive area and at least a portion of an area in which the black matrix is disposed, and
wherein the organic pattern layer is disposed in the opening area of the second electrode.

17. The transparent display device of claim 16, wherein the organic pattern layer is in contact with the second electrode along a side surface of the organic pattern layer.

18. The transparent display device of claim 16, wherein at least a portion of the organic pattern layer overlaps with the black matrix.

19. The transparent display device of claim 16, wherein an upper surface of the second electrode has a same height as an upper surface of the organic pattern layer.

20. The transparent display device of claim 16, wherein the second electrode has a same thickness as the organic pattern layer.

21. The transparent display device of claim 16, wherein the second electrode comprises a first material having a conductivity, and
wherein the organic pattern layer comprises a second material from which the first material is desorbed.

22. The transparent display device of claim 16, further comprising a planarization layer disposed below the light emitting device in the emission area,
wherein the planarization layer comprises an upper surface and an inclined surface disposed between the upper surface and the transmissive area, and
wherein the opening area of the second electrode overlaps with an area in which the inclined surface of the planarization layer is disposed.

23. The transparent display device of claim 22, further comprising a bank disposed between the first electrode and the transmissive area,
wherein the bank comprises an upper surface and an inclined surface disposed between the upper surface and the transmissive area, and
wherein the opening area of the second electrode overlaps with an area in which the inclined surface of the bank is disposed.

24. The transparent display device of claim 23, wherein an end of the organic pattern layer is disposed on the upper surface of the bank.

25. The transparent display device of claim 22, wherein a border between the second electrode and the organic pattern layer is disposed in a first opening area of the planarization layer overlapping the transmissive area.
